(19) United States
(12) Patent Application Publication
(10) Pub. No.: US 2023/0298858 A1
(43) Pub. Date: Sep. 21, 2023

(54) PLASMA DEVICE FOR GAS-BASED SURFACE TREATMENT AND WATER ACTIVATION

(71) Applicant: The Regents of the University of Michigan, Ann Arbor, MI (US)

(72) Inventors: John Foster, Ann Arbor, MI (US); Mirko Gamba, Ann Arbor, MI (US)

(21) Appl. No.: 18/021,309

(22) PCT Filed: Aug. 13, 2021
(86) PCT No.: PCT/US2021/045947

§ 371 Date: Feb. 14, 2023

Related U.S. Application Data
(60) Provisional application No. 63/065,637, filed on Aug. 14, 2020.
(60) Provisional application No. 63/146,386, filed on Feb. 5, 2021.

(51) Int. Cl. H01J 37/32

(52) U.S. Cl. CPC H01J 37/32348; H01J 37/32449; H01J 37/32853; H01J 37/32825

(57) ABSTRACT

A surface treatment device includes a body and a plasma source disposed within the body. The plasma source includes a first inlet through the body and an ionization wave generator adjacent the first inlet to receive feedstock gas via the first inlet. The ionization wave generator includes a dielectric tube that necks down to define an elongated throat. The surface treatment device also includes a second inlet through the body and an expansion nozzle disposed within the body downstream of the second inlet. The second inlet is disposed at the elongated throat to provide further feedstock gas.

### CROSS-REFERENCE TO RELATED APPLICATION

This application claims the benefit of U.S. provisional application entitled “Plasma Wand, Gas-Based Surface Treatment,” filed Aug. 14, 2020, and assigned Ser. No. 63/065,637, and U.S. provisional application entitled “Plasma Device for Gas-Based Surface Treatment and Water Activation,” filed Feb. 5, 2021, and assigned Ser. No. 63/146,386, the entire disclosures of which are hereby expressly incorporated by reference.

### STATEMENT REGARDING FEDERALLY SPONSORED RESEARCH OR DEVELOPMENT

This invention was made with government support under IIP2027876 awarded by the National Science Foundation. The government has certain rights in the invention.

### BACKGROUND OF THE DISCLOSURE

### Field of the Disclosure

The disclosure relates generally to plasma-activated, gas-based surface treatment and water activation.

### Brief Description of Related Technology

Non-thermal plasmas have demonstrated the capacity to destroy surface contagions without damage to the surface. Plasmas possess essentially all the characteristics of an ideal disinfectant as described by the Center for Disease Control (CDC). Plasma treatment is a dry process and does not leave behind long-lived toxic remnants. Contact time can be considerably shorter than liquid cleaners. Using plasmas for treatment purposes have other advantages as well. For instance, no consumables are needed. Plasma can be created from regular (i.e., ambient) air, resulting in significant cost savings in comparison to conventional disinfectants. Plasmas are also non-selective, meaning that a reactive plasma air gas destroys all contaminants via advanced oxidation or reductive processes, whereas usually a specific disinfectant needs to be applied for certain contagions such as the corona virus. Further, plasmas are sustainable. The use of plasma eliminates the waste disposal problem such as wipes and cleaners and thus has the potential for a green and waste free approach.

Atmospheric plasmas are produced in regular room or indoor air. Typically, plasmas are generated by the application of high voltage radio frequency or periodic pulses. When the voltage between the interelectrode gap reaches the breakdown voltage of air at ambient pressure (typically at an electric field of 30,000 V/cm at 1 Atm), a streamer discharge is formed. A streamer is a filamentary plasma structure that propagates from the vicinity of one electrode to another, much like how lightning propagates from a cloud to the ground. Along the way, the streamer produces copious amounts of reactive species that can be used for sterilization such as a hydroxyl group (OH), ozone and singlet oxygen. If air is used as the feed gas, this can lead to heating of the gas owing to collisional processes and relaxation of excited molecular states which further amplifies the ionization wave. In general, plasma conditions in the streamer typically has an electron temperature of ˜10 eV, a plasma density of typically ˜10¹⁴/cc, and a propagation speed of ˜10⁷ cm/s. If the streamer reaches an opposite electrode, the channel intensifies leading to a hot spark where significant energy goes into heating the gas and not the selective production of reactive species. By applying short duration voltage pulses, the discharge can be terminated before the spark forms, thereby allowing it to remain non-thermal. The use of a gas like helium, which has good thermal conductivity and high ionization potential, is often used to circumvent this heating instability. Because the discharges operate in regular air, the diffusion path is small (i.e., on the order of micrometers), so the plasma is inherently filamentary and small in volume. Thus, the source treatment footprint is small.

However, there are a number of challenges associated with atmospheric pressure non-thermal plasmas. Scalability is one problem associated with atmospheric pressure non-thermal plasmas. The filamentary nature of the plasmas precludes the treatment of reasonably sized surfaces due to discharge characteristics, such as diameter (10s of micrometers). Temperature is another concern, such as operating at low temperatures. To achieve room temperature operation, the discharge flow gas is often helium for reasons mentioned above. Helium, however, is an expensive feed gas. Another problem with atmospheric pressure non-thermal plasmas is their stability. Jets and dielectric barrier discharge type applicators require a well-defined ground and device operating characteristics can change depending on the grounding nature of the substrate. Even surface texture/porosity, dielectric properties, and angle of the jet relative to surface affects operation and thus flux to surface. Therefore, operation of conventional atmospheric pressure non-thermal plasmas is situation-dependent, making it particularly problematic for treatment applications.

Effectiveness over a broad spectrum of microbes and short contact times are desirable considerations for a disinfectant. Short contact times are needed by many applications to meet rapid turnover, such as hospital rooms or airplanes. In addition, not all surfaces can immediately be disinfected with traditional approaches, such as wet methods or UV light exposure. For example, some surfaces are porous and retain liquids, such as the seats of a bus or those of an airplane. Thus, a wet-based disinfection approach may not be effective if rapid turnaround is required. A universal problem for users that require cleaners for disinfection is the added cost of replacing consumables. With the current pandemic, the use of cleaners has increased substantially, thus increasing operating costs and waste. The public is likely to demand more stringent cleaning protocols of public spaces post pandemic as well. Therefore, there is a need for an economical, reasonably portable, effective disinfection method that does not require long contact times.

### SUMMARY OF THE DISCLOSURE

In accordance with one aspect of the disclosure, a surface treatment device includes a body and a plasma source disposed within the body. The plasma source includes a first inlet through the body and an ionization wave generator adjacent the first inlet to receive feedstock gas via the first inlet. The ionization wave generator includes a dielectric tube that necks down to define an elongated throat. The surface treatment device also includes a second inlet through the body and an expansion nozzle disposed within the body downstream of the second inlet. The second inlet is disposed at the elongated throat to provide further feedstock gas.

In accordance with another aspect of the disclosure, a handheld surface treatment device includes a grounded body including an inner hollow portion. The inner hollow portion has an upstream end and a downstream end. The handheld surface treatment device also includes a plasma source disposed in the inner hollow portion of the grounded body. The plasma source includes a primary flow injector and a dielectric tube including a primary section and an extended throat section, the primary section tapering down to the extended throat section, such that the extended throat section is narrower than the primary section. The plasma source also includes an electrode coaxially disposed in the primary section and the extended throat section of the dielectric tube. The handheld surface treatment device also includes a secondary flow injector through a wall of the grounded body, the secondary flow injector in fluid communication with the inner hollow portion of the grounded body. The handheld surface treatment device also includes a distributor in fluid communication with the downstream end of the inner hollow portion of the grounded body.

In accordance with yet another aspect of the disclosure, a method of treating a surface with a device, the device including a body, a first inlet, an ionization wave generator, and a distributor, the body having an inside portion, the ionization wave generator including a dielectric tube, includes receiving, by the first inlet, air as input gas. The method of treating a surface with a device also includes generating, by the ionization wave generator and a plasma source, a flow of reactive species based on the received input gas. The method of treating a surface with a device also includes accelerating the flow of reactive species based on a geometry of the inside portion of the body of the device. The method of treating a surface with a device also includes distributing, by the distributor, the accelerated flow of reactive species to treat the surface.

In accordance with yet another aspect of the disclosure, a system for generating plasma-activated water includes a water reservoir configured to hold a volume of water. The system for generating plasma-activated water also includes a plasma device coupled to the water reservoir, the plasma device including a body and a plasma source disposed within the body, where the plasma device is configured to generate a flow of reactive gases produced by the plasma source to activate the water, where a geometry of the body of the plasma device is configured to accelerate the flow of reactive gases, and where the plasma device further includes an inlet port positioned to provide additional gas to mix with the generated flow of reactive gases.

In connection with any one of the aforementioned aspects, the devices and/or methods described herein may alternatively or additionally include or involve any combination of one or more of the following aspects or features. The ionization wave generator includes an electrode that extends through the elongated throat. The dielectric tube includes a primary section adjacent the first inlet and a converging nozzle section between the primary section and the elongated throat. The ionization wave generator includes an electrode coaxially disposed in the dielectric tube, the electrode having a first section in the primary section and a second section in the elongated throat, the second section being narrower than the first section. The second inlet is disposed at an axial position along the elongated throat to flush reactive species generated between the body and the elongated throat. The second inlet is disposed at an axial position along the elongated throat to cool the dielectric tube along the elongated throat. The feedstock gas includes air. The second inlet includes a flow injector tube to provide the further feedstock gas. The further feedstock gas provides a cooling flow to control a temperature of the elongated throat. The surface treatment device further includes a distributor plenum in fluid communication with the expansion nozzle. The distributor plenum includes a plurality of exit nozzles. The plurality of exit nozzles are configured to distribute flow evenly through the plurality of exit nozzles. The ionization wave generator is configured to generate a pulsed corona line-in-cylinder discharge, where reactive species are produced by the pulsed corona line-in-cylinder discharge. The surface treatment device further includes a brush coupled to the body, the brush being configured to engage a surface for treatment. The surface treatment device further includes a water dispenser in fluid communication with the plasma source to provide plasma activated water to the surface for treatment. The primary flow injector is adjacent the upstream end of the inner hollow portion of the grounded body. The inner hollow portion includes a tubular section adjacent the upstream end and a nozzle section adjacent the downstream end. The extended throat section of the dielectric tube extends from the tubular section into the nozzle section of the inner hollow portion of the grounded body. The secondary flow injector is disposed upstream of the nozzle section of the inner hollow portion of the grounded body. The generating includes activating, by an electrode of the ionization wave generator, the input gas along the dielectric tube. The method of treating a surface with a device further includes receiving, by a second inlet, additional feed gas to mix with the generated flow of reactive species. The method of treating a surface with a device further includes controlling a temperature of the dielectric tube with the received additional feed gas. The method of treating a surface with a device further includes controlling gas-phase chemistry of the flow of reactive species with the received additional feed gas. The method of treating a surface with a device further includes controlling a flow speed and residence time of the flow of reactive species to optimize the generation of the flow of reactive species. The method of treating a surface with a device further includes providing, by a water source coupled to the body of the device, water into the body of the device, the water source being in fluid communication with the accelerated flow of reactive species, such that the water absorbs at least a portion of the reactive species. The distributing includes dispensing the water through a brush coupled to the body of the device to clean and disinfect the surface. The body of the plasma device includes converging walls to define the geometry of the body of the plasma device configured to accelerate the flow of reactive gases. The water reservoir includes an inlet having a water flow controller. The system for generating plasma-activated water also includes a sensor disposed inside the water reservoir, the sensor being configured to measure a characteristic of the volume of water in the water reservoir. The system for generating plasma-activated water also includes a controller in communication with the water flow controller of the inlet, the sensor, and a power supply of the plasma device, where the controller is configured to control water level of the volume of water via the water flow controller and activation of the plasma device via the power supply based on the measured characteristic of the volume of water. The characteristic is a concentration of a reactive gas. The controller is configured to discontinue operation of the plasma device when the water level of the volume of water is below a predetermined threshold. The plasma device is configured to control a temperature of the flow of reactive gases via the additional gas. The plasma device is configured to control a gas-phase chemistry of the flow of reactive gases via the additional gas. The plasma device is configured to control a ratio of the reactive gases to the additional gas to control a concentration of reactive species in the volume of water. The reactive species comprises reactive nitrogen species. The ratio falls in a range from about 5 to 1 to about 2 to 1.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 illustrates a surface treatment device in accordance with one example.

FIG. 2 illustrates a cross-sectional view of a surface treatment device in accordance with one example.

FIG. 3 illustrates a side view of a surface treatment device in accordance with one example.

FIG. 4 illustrates a flow chart depicting a method of treating a surface in accordance with one example.

FIG. 5 illustrates a system for generating plasma-activated water in accordance with several examples.

The embodiments of the disclosed devices, systems and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Devices for treating surfaces are described. Methods for using such devices are also described. The disclosed systems, methods and devices generally include a surface treatment device, or plasma wand, that includes a body and a plasma source attached to or disposed within the body. The plasma source includes a first inlet for providing source gas, or feedstock gas. The plasma source also includes an ionization wave generator that receives the feedstock gas from the first inlet. The ionization wave generator includes a dielectric tube that necks down to define an elongated throat. The plasma wand also includes a second inlet through the body at the elongated throat to provide additional feedstock gases. The plasma wand further includes an expansion nozzle within the body and downstream of the second inlet. Systems and methods for generating plasma-activated water using a plasma device are also described.

In addition to the elongated throat, the dielectric tube may include a primary section adjacent the first inlet and a converging nozzle section between the primary section and the elongated throat. The ionization wave generator includes an electrode that extends through the dielectric tube, including the elongated throat. The dielectric tube and electrode that make up the ionization wave generator may also be referred to as a plasma tube. The second inlet may include a flow injector tube to provide additional gases and may be positioned axially along the elongated throat to flush reactive species generated between the body and the elongated throat and to cool the dielectric tube along the elongated throat. The plasma wand may also include a distributor plenum in fluid communication with the expansion nozzle, where the distributor plenum includes a plurality of exit nozzles that are configured to distribute flow evenly. The body of the plasma wand may be tubular or cylindrical and may be grounded. The plasma wand may also include a brush attachment and a water dispenser to further aid in the treatment of a surface.

The disclosed plasma wand operates on the principle of disinfection through rapid oxidation of organic matter, such as bacteria and viruses, by reactive oxygen species produced by plasma activation of ambient air. The plasma wand enables contactless rapid surface disinfection that can be applied to both hard (e.g., plastic, metal, and the like) and soft (e.g., fabric) surfaces regardless of their morphology. The plasma wand does not leave any residue, is nonselective, non-toxic, and intrinsically a dry process, does not damage the surface and does not require single-use consumables or chemicals to achieve its function—it simply uses ambient air as the renewable precursor. The disclosed plasma wand can be applied to control bacterial and viral spreads during a pandemic, but it can also find common use, or be integrated into production processes and public infrastructure that require a continuous, effective, low cost and environmentally conscious disinfection solution. The disclosed plasma wand is a response to the current COVID-19 pandemic, but it is effective at controlling any infection spread.

It is well-known that a range of infections are spread by direct contact with surfaces contaminated with bacterial and viral particles. Contaminated surfaces in public spaces can lead to an outbreak through person-to-person contact subsequent to exposure. Some surfaces in public spaces are particularly problematic, such as seats on buses and airplanes, chairs in classrooms and restaurants, hospital bed railings/side tables, dormitories/barracks, ships, and factory stations. These surfaces can be cleaned with conventional disinfectants to high levels provided the contact time is sufficiently long, which can approach 0.5 hrs, but which is incompatible to customer needs, which is on the order of 1 minute. Therefore, there is a need for an economical, reasonably portable, effective disinfection method that does not require long contact times.

The proposed device may therefore support a range of markets ranging from hospitality (hotels, casinos, amusement parks, cruise ships and restaurants), mass transit (trains and buses), airlines/airports, schools (classrooms/dormitories), and gyms.

For example, mass transit is expected to greatly increase cleaning frequency rather than nightly as was common practice before the pandemic. Wet cleaners, which require finite drying times, may not be suitable given schedule requirements. Fast turnaround times are necessary and will require fast treatment.

In another example, the hospitality sector involves rapid customer turnover and thus the potential of transmission can be high. For example, tables and booths in restaurants will require disinfection before and after each guest. Frequent cleaning is a potential solution, but cleaners represent an added cost both for precursors and disposal. New technologies that can clean rapidly without the need for consumables addresses the added labor costs as well as cost of cleaners. The increased use of cleaners is not sustainable from an environmental standpoint. Cleaners such as quaternary ammonia has shown to have negative effects on the environment. Additionally, regular exposure to these cleaners can lead to lung disease such as chronic obstructive pulmonary disease (COPD) as well as infertility. In this case, there is a need for effective disinfection technologies that can rapidly treat surfaces while minimizing the release of potentially toxic vapors. UV can be harmful to humans as well and thus requires additional safety measures and additional trained staff to operate.

In the airline industry, guidelines call for increased frequency of cleaning including stop overs (wet cleaning) and end-of-flight (deep cleaning). Typical post flight recommendations are to clean all internal surfaces (e.g. seats, carpet, PVC floor, tray tables, and the like). The increased cleaning frequency translates into added cost for cleaning consumables. In regard to stopovers, to maintain schedule, it is desirable that treatments are quick and effective, which opens the door for new, dry technologies such as plasma methods.

In the restaurant industry, increased frequency of high touch surfaces will be required—including doorknobs, sink knobs, handles and surfaces in bathrooms, the table surface under the tablecloth, handles and salt and pepper shakers, in addition to seating and booth benches.

The proposed device may also be used in sterilization entrance portals onto planes or even into office buildings where the entering person is the surface to be sterilized. The disclosed plasma wand disinfects by producing multiple jets of reactive oxygen species (ROS). Oxidation via chemicals such as bleach is an effective means of disinfection. Oxidation destroys DNA/RNA, damages protein structure, and destroys the integrity of protective membranes. The chief issue and impediment to the application of plasma-based devices despite their promise for disinfection is scaleup and efficacy at scale. Plasmas made in regular air are filamentary and thus cannot be used to treat large surfaces practically. The proposed device addresses scale-up by implementing a gas-dynamic design combined with a reacting plasma flow chamber to optimize delivered oxidant dose to a surface to be treated. Advantages of the proposed device is that it operates on air, does not directly expose surfaces or personnel to high voltage, has a large treatment footprint, and the delivered treatment or disinfecting dose can be tailored both in magnitude and composition for different applications.

Generally speaking, the disclosed plasma wand is a nonthermal reacting flow reactor activated by plasma that is capable of producing a neutral beam of reactive species for the purpose of surface treatment, such as disinfection. The plasma wand generates high speed jets of reactive oxygen species (or reactive nitrogen species if desired) in order to treat surfaces. The plasma wand relies on gas dynamic principles to evacuate reactive species to a surface before the reactive species decay. In other words, the plasma wand uses plasma to active a working gas (air) and then quickly distribute the activated gas uniformly through an applicator head (distributor) to the surface in a fraction of the lifetime of the active species (typically 1 second or less in air). This is enabled by using a distributed plasma internal to the device, and controlling its chemistry through a combination of plasma and gas dynamics processes, such as the use of dilution and gas acceleration through nozzles to cool the discharge tube as well as to rapidly deliver the reactive species to the surface within a fraction of their gas phase lifetime.

The disclosed plasma wand is a surface treatment device designed for a range of applications including the disinfection of surfaces, the decontamination of surfaces (toxic chemical) and the activation of surfaces for additional chemical processing. The plasma wand does not directly expose surfaces to plasma, which can damage the substrate or surface on which it is applied, rather the plasma wand device is a plasma reactor that takes input feed gas such as air and activates it, producing long lived (seconds to hours lifetime) species—such as peroxide and ozone—as well as highly reactive short lived (on the order of seconds) species—such as singlet oxygen and OH radicals. The interaction of this nonequilibrium plasma with the input gas creates copious amounts of reactive oxygen, reactive nitrogen species and precursor-derived radicals. By using a controllable plasma source, the chemistry and composition of the plasma-activated gas can be controlled and tailored to specific applications. The activated gas is flushed out of a manifold distributor to uniformly immerse the surface below the applicator. In the case of disinfecting or sterilizing a surface, the reactive species destroy virus, mold and bacterial via advanced oxidation.

The disclosed plasma wand is an approach that utilizes plasma production methods similar to a plasma jet and other nonthermal methods but to utilize that plasma not as the direct disinfecting agent but rather as a source of energetic electrons and ultraviolet light to drive gas-phase plasma reactions. The reactions of interest are those that create reactive oxygen species. This approach mitigates direct plasma contact with the surface which can damage the surface—particularly soft surfaces—since at atmospheric pressure (1 atm), air plasmas tend to be filamentary, which can cause localized heating and subsequent damage. The decoupling of the reactive gas treating the surface from its plasma generation eliminates direct plasma surface damage derived from filamentary streamer formation onto the surface that lead to surface pinhole formation, surface erosion thermal damage and ablation. Methods using the disclosed plasma wand may avoid the use of plasma activated water as well and may thus be a gas phase treatment—avoiding residue that could contain byproducts that may themselves be toxic or preclude gases reactants from reaching the surface.

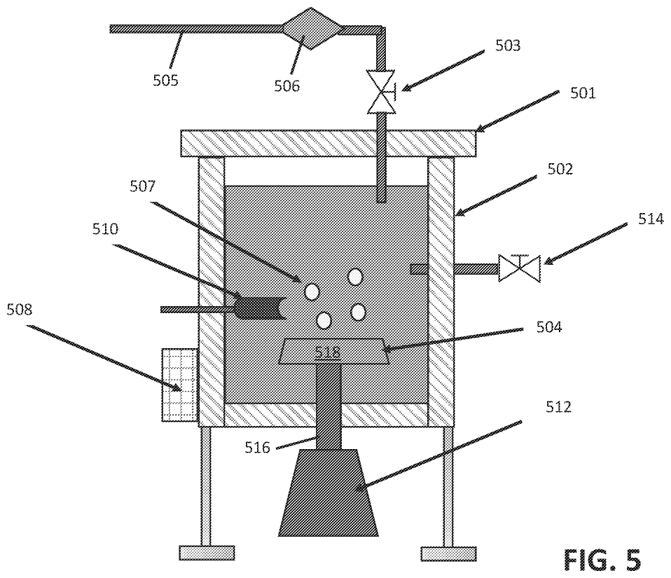

Although described in connection with disinfecting surfaces, such as disinfecting public spaces, including hospitals, schools, office buildings, gyms, and public modes of transport (e.g., aircraft, buses, and taxis/ride share cars), the disclosed systems, methods and devices may be applied to a wide variety of applications. The disclosed device may also be used to disinfect cargo, packages/mail, and other items that travel and pass from person to person. The device can also be used for the surface decontamination of toxic chemicals (e.g. 1,4 dioxane, pesticides) or surface preparation for industrial processing. Surfaces that require oxidizing or stripping can also be treated with the disclosed plasma wand applicator. The reactive species generated by the disclosed plasma wand can also change the contact angle of polymer surfaces. Various deposition and surface reaction chemistries are possible depending on the precursor gases used. Such a system can also be used to decontaminate living tissue, such as human tissue, and food products, such as vegetables, as well. The disclosed plasma wand may also be used for deodorizing, such as in restaurants. In another example, the disclosed method and device may be used to clean and disinfect electronics, since the risk of charging those electronics with the plasma of the disclosed device is minimized. In another example, the disclosed method and device may also be used in an industrial production process to clean and/or disinfect a product, or part of a product, at a particular point along a continuous production line. Thus, the disclosed surface treatment device may be used in various settings and industries, such as hospitality (hotels and restaurants), mass transportation (buses and trains), airline (planes and concourse seating), medical, education, industrial/manufacturing, chemical, textiles, retail, fitness, and household spaces. Further, as discussed below with reference to FIG. 5, the disclosed device may also be used to produce plasma-activated water, which may render the water potable or into a source of disinfectant (i.e., turn the water into an antimicrobial solution).

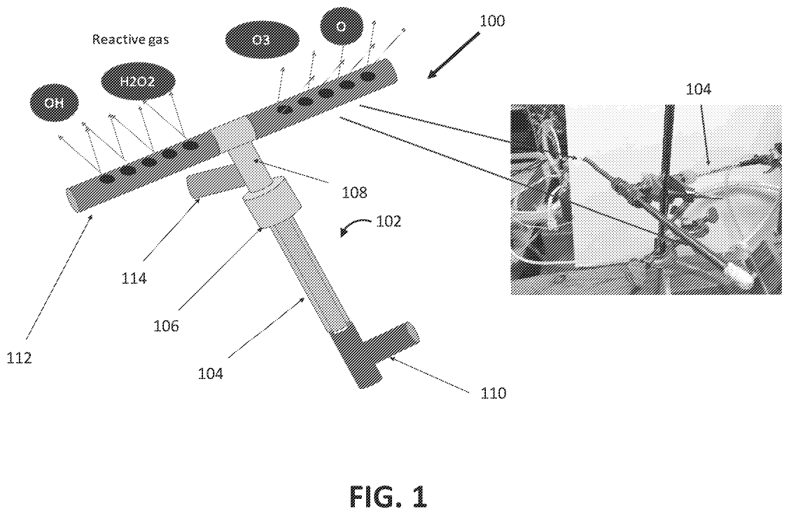

FIG. 1 depicts a surface treatment device 100 in accordance with one example. In the example shown in FIG. 1, the surface treatment device 100, or plasma wand 100, includes a central body 102 having a plasma tube 104, a plasma exit section 106, and a reaction chamber 108. At one end (i.e., an upstream end) of the body 102 is a plasma source gas feed and power fitting 110, which is attached to the plasma tube 104. At the other end (i.e., downstream end) of the body 102, attached to and in fluid communication with the reaction chamber 108, is a plasma wand applicator 112 with exit plenum holes that allow reactive gases, such as ozone, singlet oxygen, hydrogen peroxide and a hydroxyl radical to exit the plasma wand applicator 112. The plasma wand 100 of FIG. 1 also includes a precursor gas feed 114 attached to the reaction chamber 108. The plasma wand applicator 112, the body 102, or both may be grounded to avoid shock hazard.

The plasma source gas feed and power fitting 110 may also be referred to as an inlet 110, such as a first inlet 110, or a primary flow injector 110, as described below. The plasma source inlet 110 may go through the body 102 of the plasma wand 100 (i.e., at least one wall of the body 102) or may be coupled to the plasma wand body 102 such that the inlet 110 and the body 102 are axially adjacent (i.e., the inlet 110 and the body 102 may connect end-to-end). The inlet 110 may receive feedstock gas, such as air. While the feedstock gas may be only air, it may also be a combination of precursor gases and/or water vapor that are chemically activated by the nonthermal plasma, as will be discussed below.

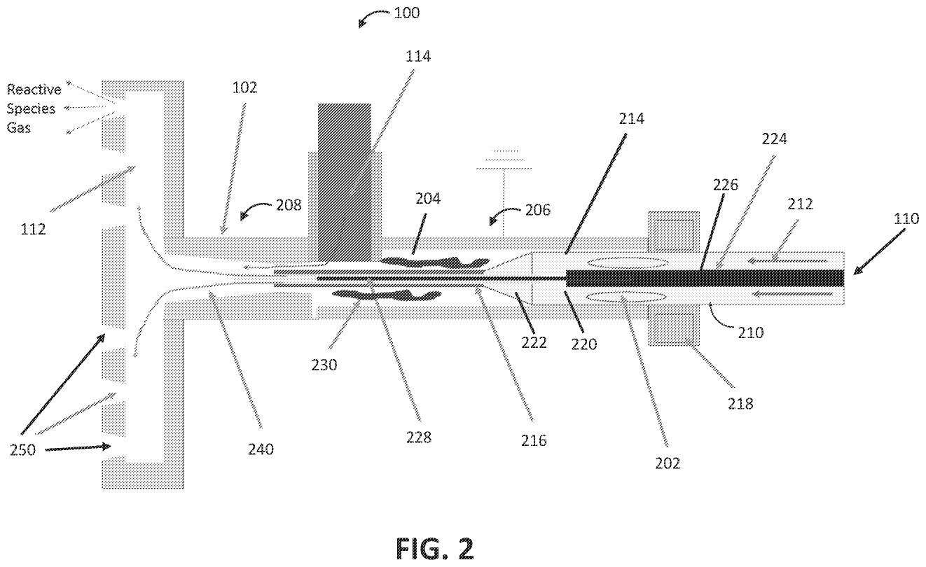

The body 102 of the plasma wand 100 includes an inner hollow portion, fluid channel, or bore, between the two ends, such that the plasma source gas feed and power fitting 110 (i.e., inlet 110) at the upstream end is in fluid communication with the plasma wand applicator 112 at the downstream end. In other words, fluid may enter the body 102 of the plasma wand 100 at the plasma source gas feed and power fitting 110, travel through the plasma tube 104, plasma exit section 106, and reaction chamber 108 into the plasma wand applicator 112 where the fluid then exits out the exit plenum holes of the applicator 112. In this respect, the plasma wand 100 is a continuous flow device with the precursor feedstock that passes through the plasma and becomes activated. Activation is facilitated through interaction of input gas with fields, electrons, excited species and UV associated with the plasma. At least a portion of the body 102 of the plasma wand 100 may be cylindrically shaped. Details of the inside of the various components of the plasma wand 100 will be discussed below with reference to the cross-section of the plasma wand 100 shown in FIG. 2.

The plasma tube 104 is a hybridization of a coaxial ionization wave generator and a pulsed corona line-in-cylinder discharge to produce a range of reactive species. The plasma tube 104 may also be referred to as a dielectric tube and may be made of quartz, but other materials are possible. The plasma tube 104 includes an electrode, which may be centrally located along a longitudinal axis of the plasma tube 104, as will be discussed below. The electrode inside the plasma tube 104 is a powered electrode that generates an ionization wave. Application of a voltage pulse to this central electrode leads to the formation of an ionization wave that ionizes input gas and produces reactive species. The ionization wave is distributed along the length of the plasma tube 104 and activates the input gas (i.e., air) along the way. The gas flow along the plasma tube 104 passes through a converging nozzle and, according to gas dynamic principles, increases speed as it reaches the plasma exit section 106. The ionization wave generates plasma that diffuses down through the converging nozzle section of the plasma tube 104.

The plasma exit section 106 is the section of the plasma wand body 102 between the plasma tube 104 and the reaction chamber 108. The plasma exit section 106 is where plasma leaves the plasma tube 104 prior to entering the reaction chamber 108 and is mixed with corona produced species generated in the plasma tube 104 upstream of the plasma exit section 106.

The reaction chamber 108 is immediately downstream of the plasma exit section 106. The reaction chamber 108 includes an expansion nozzle. The precursor gas feed 114 is attached to, and in fluid communication with, the reaction chamber 108. The precursor gas feed 114 may also be referred to as an inlet, such as a second inlet 114, or a secondary flow injector 114, as described below. The precursor gas feed 114 may go through the body 102 of the plasma wand 100 (i.e., at least one wall of the reaction chamber 108). The precursor gas feed 114 may provide additional or further feed gas, such as air. While the feed gas may be only air, it may also be a combination of precursor gases and/or water vapor that are chemically activated by the nonthermal plasma. The purpose of this feed gas is to convectively cool at least a portion of the plasma tube 104. The gas from the precursor gas feed 114 can also be seeded with water or any chemical precursor to interact with the plasma generated in this section and at the plasma exit section 106 downstream of the plasma tube 104. In this manner the chemistry can be tailored by mixing the plasma leaving the plasma tube 104 and the corona produced species generated in the plasma tube 104 upstream of the plasma exit section 106 with the additional feed gases provided by the precursor gas feed 114.

The gases that are mixed in a diverging section of the reaction chamber 108 (i.e., area within the expansion nozzle of the reaction chamber 108) are flushed out into the plasma wand applicator 112 as the gas speed increases, again according to gas dynamic principles. The residence time of the reactive species (i.e., the time the gases spend in a particular place) can be controlled by the nozzle expansion ratio of the expansion nozzle of the reaction chamber 108. The combination of the converging nozzle of the plasma tube 104 and the expansion nozzle of the reaction chamber 108 work together to operate as a converging-diverging nozzle, otherwise referred to as a CD nozzle, con-di nozzle, or de Laval nozzle. The high-speed flow produced by this converging-diverging nozzle geometry allows short lived species to exit the plasma zone prior to decaying and to prevent destructive thermally dependent reverse reactions or reactions that create NOx products. In another example, the reaction chamber 108 may include other geometries in addition to, or in lieu of, the expansion nozzle. For instance, instead of the expansion nozzle geometry, the reaction chamber 108 may have a geometry matching the geometry of the plasma exit section 106 of the plasma tube 104. In another example, the geometry of the reaction chamber 108 may include another converging nozzle.

In one example, the plasma wand applicator 112 is much like an applicator of a vacuum cleaner attachment head in that the applicator 112 extends laterally from, and perpendicular to, the reaction chamber 108. In this regard, the plasma wand applicator 112 and the plasma wand body 102 create a T-shape device, as shown in FIG. 1. The plasma wand applicator 112 may also be referred to as a distributor 112, or distributor plenum 112, and is in fluid communication with the expansion nozzle of the reaction chamber 108. The plasma wand applicator 112 is perforated with a plurality of exit nozzles, or exit plenum holes, designed and configured to evenly distribute the plasma-activated gas flowing from the reaction chamber 108. In this regard, the exit plenum holes may be sized such that flow through the exit plenum holes are substantially uniform. As shown in FIG. 1, the reactive gases that may exit the exit plenum holes of the plasma wand applicator 112 include a hydroxyl radical (OH), hydrogen peroxide (H₂O₂), ozone (O₃), and singlet oxygen (O₂ or ¹O₂). The high-speed flow of these gases is injected into a plenum that is used to distribute the species to a surface through the applicator 112. The delivered dose of these gases to the surface is a function of the gas flow rate, exposure time, the plasma discharge power, and the nature of the precursor gases. As mentioned above, the applicator head 112 is at ground potential and thus can be in contact with most surfaces without arcing. This also assures reliable device operation regardless of where the effective ground plane in the room is located—an issue with stand-alone plasma sources and jets—since the ground potential surface is set due to the body being grounded.

FIG. 2 depicts a cross-sectional view of a surface treatment device, such as the plasma wand 100 of FIG. 1 discussed above. The surface treatment device 100 may be a handheld surface treatment device 100. The surface treatment device 100 includes a body 102 and a plasma source 202. The body 102 may be a grounded body 102, and includes an inner hollow portion 204, or bore 204, having an upstream end and a downstream end. With respect to FIG. 2, the upstream end is to the right and the downstream end is to the left. The inner hollow portion 204 includes a tubular section 206 adjacent the upstream end and a nozzle section 208 adjacent the downstream end. The tubular section 206 and nozzle section 208 correspond to the plasma tube 104 and reaction chamber 108 of FIG. 1, respectively.

The plasma source 202 is disposed within the body 102. More specifically, the plasma source 202 is disposed in the inner hollow portion 204 of the grounded body 102. The plasma source 202 includes a first inlet 110, or primary flow injector 110, through the body 102 and an ionization wave generator 210 adjacent the first inlet 110 to receive feedstock gas 212 via the first inlet 110. The feedstock gas 212 may be air, but other gases may be used. The first inlet 110, or primary flow injector 110, is adjacent the upstream end of the inner hollow portion 204 of the grounded body 102. The plasma source 202 itself may be a plasma jet or an array of micro discharges. As will be discussed in more detail below, the induced chemistry (electron energetics) may be optimized based on the discharge type.

The ionization wave generator 210 includes a dielectric tube 214 that necks down to define an elongated throat 216, or extended throat section 216. The extended throat section 216 of the dielectric tube 214 extends from the tubular section 206 into the nozzle section 208 of the inner hollow portion 204 of the grounded body 102. The dielectric tube 214, or plasma tube 214, which may be a quartz tube 214, may be positioned or received within the inner hollow portion 204 of the body 102 of the surface treatment device 100 and secured with a sealing nut 218. The dielectric tube 214 includes a primary section 220 adjacent the first inlet 110 and a converging nozzle section 222 between the primary section 220 and the elongated throat 216. In other words, the primary section 220 tapers down (at the converging nozzle section 222) to the extended throat section 216, such that the extended throat section 216 is narrower than the primary section 220.

The ionization wave generator 210 includes an electrode 224 coaxially disposed in the dielectric tube 214. The electrode 224 includes a first section 226 in the primary section 220 and a second section 228 in the elongated throat 216, the second section 228 being narrower than the first section 226. In this regard, the electrode 224 extends through the elongated throat 216. In other words, the electrode 224 is coaxially disposed in both the primary section 220 and the extended throat section 216 of the dielectric tube 214. The first section 226 of the electrode 224 may be referred to as the central electrode 226 and the second section 228 of the electrode 224 may be referred to as the extension electrode 228. In this way, the extension electrode 228 extends from the central electrode 226 and is centered along the axis of the extended throat section 216. This geometry allows for ozone to be generated efficiently in the extended throat section 216. An advantage of the extended throat section 216 of the dielectric tube 214 is that it prevents micro discharges, or streamers, that emanate from the surface of the electrode 224 from attaching directly to ground. Such attachment would produce a hot spark which precludes the production of ozone. Rather, the narrow electrode is insulated and capacitively coupled to ground and efficiently produces ozone. The ionization wave generator 210 is configured to generate a pulsed corona line-in-cylinder discharge, where reactive species are produced by the pulsed corona line-in-cylinder discharge. As shown in FIG. 2, there is a corona production region 230 between the elongated throat 216 and the body 102 of the device 100.

The surface treatment device 100 also includes a second inlet 114, or secondary flow injector 114 (i.e., tube), through the body 102, or through at least a wall of the body 102. The second inlet 114 is in fluid communication with the inner hollow portion 204 of the grounded body 102 and is disposed upstream of the nozzle section 208 of the inner hollow portion 204 of the grounded body 102. In the example shown in FIG. 2, the second inlet 114 is disposed at the elongated throat 216 to provide further feedstock gas. In this regard, the second inlet 114 includes a flow injector tube to provide the further feedstock gas. The second inlet 114 is disposed at an axial position along the elongated throat 216 to flush reactive species generated between the body 102 and the elongated throat 216, such as the corona produced species discussed above. The second inlet 114 is also disposed at an axial position along the elongated throat 216 to cool the dielectric tube 214 along the elongated throat 216. More specifically, the further feedstock gas from the second inlet 114 provides a cooling flow to control a temperature of the elongated throat 216. This secondary flow allows for control of reaction zone temperature and therefore allows for the optimization of the plasma chemistry and in particular the optimization of ozone production.

An important oxidizer generated in the plasma source 202 is ozone. Ozone is a powerful disinfectant and is thus widely used in the water treatment industry. Production of this important compound is complex and highly dependent on plasma conditions. The theoretical thermodynamic limit for ozone production is 0.8 kWh/kg. In practice its production cost is much higher in the range of 15-20 kWhr/kg. In air, the presence of nitrogen and water vapor can greatly affect the production efficiency. At increased plasma gas temperatures atomic nitrogen can form. These nitrogen species can both facilitate the formation of ozone as well as compete with ozone production by forming NOx compounds. Excited nitrogen interacting with molecular oxygen to produce atomic oxygen: N₂(excited)+O₂→N₂O+O and N₂(excited)+O₂→N₂+O+O which can recombine to form ozone. On the other hand, reactions such as NOx formation reduce the available atomic oxygen: O+NO+M→NO₂+M and O+NO₂+M→NO+O₂. Here M is a third body participating in the reaction at temperature. These back reactions occur at elevated temperatures (greater than room temperature) and thus control of discharge temperature is important in regard to ozone production chemistry. Nitrogen reactions that liberate atomic oxygen on the other hand take longer to develop, ˜100 microseconds in contrast to pure oxygen. In this regard, species must remain in the active plasma region of the device 100 for at least this time period to form. From a gas dynamic standpoint, the gas flow speed into the source region must assure this minimum residence time, which is orders of magnitude shorter than the lifetime of OH or singlet oxygen. Ozone is also by itself thermally fragile and will decompose as temperatures that exceed 100 Celsius: O₃+M↔O₂+O+M and O₃+O↔O₂+O₂. The chemistry is interrelated with the gas-dynamic design of the device 100 and thus again forms essentially a design loop required for ultimate optimization. Temperature can be adjusted by controlling the on-time of the high voltage breakdown pulse and the power supply frequency.

The surface treatment device 100 further includes an expansion nozzle 240 disposed within the body 102 downstream of the second inlet 114. The expansion nozzle 240 is located within the nozzle section 208 of the inner hollow portion 204 adjacent the downstream end. The converging nozzle section 222 and the expansion nozzle 240 operate as a CD nozzle, as described above. This particular geometry allows high-speed flow of reactive species that minimizes reactants residence time in the active zone. Powerful oxidizers such as the OH radical and singlet oxygen (excited state of molecular oxygen with a low lying unoccupied molecular orbital) have very short lifetimes in air. Single oxygen in air has a lifetime on the order of 50 ms in air. The OH radical in air has a lifetime on the order of 1 second. Therefore, these species must be delivered to the substrate or destination before they are removed via de-excitation or reaction with another species. Using the disclosed geometry, the plasma activated species can be accelerated through the series of nozzle sections discussed above to assure that short lived species are delivered to a surface or volume of liquid, such as water, within their lifetimes (i.e., before they decay). Thus, flow speed and residence time can be controlled to optimize reactants produced.

The surface treatment device 100 includes a distributor plenum 112 in fluid communication with the expansion nozzle 240. More specifically, the distributor plenum 112 is in fluid communication with the downstream end of the inner hollow portion 204 of the grounded body 102. The distributor plenum 112 includes a plurality of exit nozzles 250 that are configured to distribute flow evenly through the plurality of exit nozzles 250. In other words, the plurality of exit nozzles 250 are sized such that flow through the plurality of exit nozzles 250 are substantially uniform. The diameter of the holes is sized such that flow through each aperture is similar for uniform treatment. In this respect the device 100 uses a plasma source 202 and a nozzle geometry to deliver a flux of reactive species. Each of the exit nozzles 250 may have the geometry of an expansion nozzle 240 to further accelerate the flow of reactive species gas out of the distributor plenum 112 to a surface or body of liquid for treatment. In the example shown in FIGS. 1 and 2, only one plasma tube 104 or source 202 is attached to the distributor plenum 112. However, the distributor plenum 112 or applicator head 112 is scalable and multiple plasma tubes 104 may be attached to a single applicator head 112.

As discussed above, the plasma source 202 of the surface treatment device 100 is a hybridization of a coaxial ionization wave generator 210 and a pulsed corona line-in-cylinder discharge to produce a range of reactive species such as ozone, singlet oxygen, hydrogen peroxide and a hydroxyl radical. The secondary flow injector tube 114 is used to provide a combination of precursor gas as well as cooling flow to control plasma dielectric tube 214 temperature and to control plasma-gas phase chemistry. A dielectric tube 214, such as a quartz tube 214, is disposed into a grounded metal structure 102 using a gas tight fitting. The dielectric tube 214 contains a centrally mounted powered electrode 224. A sealing nut 218 and surrounding end of the tube 214 serves as ground reference.

Input gas 212, such as air, is received into the dielectric tube 214. Ambient air pumped into the plasma stage activates the gas 212 via interaction with energetic electrons. Application of a voltage pulse to the central electrode 226 leads to the formation of an ionization wave that ionizes the input gas 212 and produces reactive species. The voltage pulse used for plasma formation controls the electron energy, which in turn controls reaction rates, selects which active species are actually produced and defines their relative concentrations. The plasma source 202 itself is an optimized distributed discharge that facilitates reactive oxygen species formation while avoiding nitrogen oxide (NOx) species production. The plasma source 202 may be a plasma jet or an array of micro discharges. The ionization wave propagates along the length of the dielectric tube 214 activating the input gas 212. Flow from the dielectric tube 214 passes through a converging nozzle section 222 and achieves high speeds, in some cases sonic speed, in the extended dielectric throat section 216. The ionization wave generates seed plasma that diffuses down through the converging nozzle section 222. The secondary gas injection port 114 provides additional feed gas, such as air, to cool the extended dielectric tube 214 and to interact with the plasma exiting from the extended dielectric tube 216. In this way, secondary air flow cools the plasma tube 214 and controls plasma gas-phase chemistry to maximize oxidant production. The extended throat 216 leads to a diverging section 240 (i.e., expansion nozzle 240) allowing for the mixing of the secondary seed gas with plasma emanating from the tube 214. The expansion nozzle 240 also allows for the flushing of corona produced species generated in the gap 230 between the narrow extended dielectric tube 216 and the grounded wall of the body 102. Chemical reactions occur in the nozzle section 208 and are immediately flushed out as flow speeds increase (e.g., supersonic in some cases). In this regard, the residence time for species is short and can be controlled by the nozzle expansion ratio. The reactive gas being dynamically accelerated with a nozzle 240 allows short lived species to exit the plasma zone to prevent destructive thermally dependent reverse reactions or reactions that create NOx products. As discussed above, geometries other than an expansion nozzle 240 downstream of the extended throat section 216 are possible. These other geometries may depend on a particular type of application or use. The high-speed flow expands a second time into an applicator head 112, such as a distributor plenum 112, further accelerating. The distributor plenum 112 contains nozzle apertures 250 to disperse the gas to a surface or volume of liquid for treatment. Distribution of activated air can potentially be integrated with cleaning methods, such as integrated into a brushed applicator, vacuum or steam cleaner. In another example, activated air may be distributed to a volume of water to treat the water, such that the water becomes drinkable.

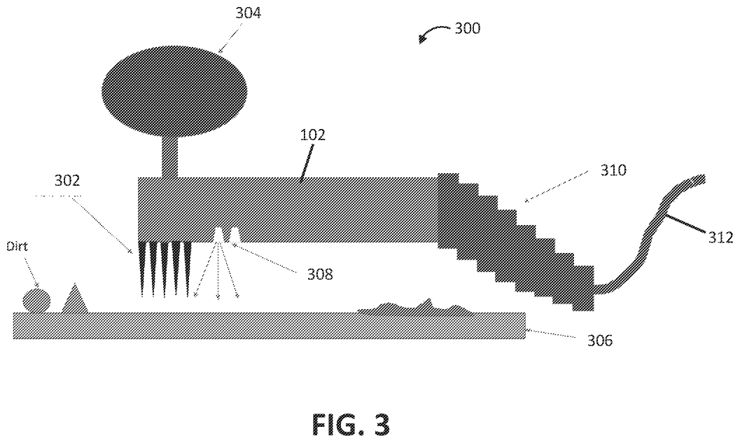

The disclosed plasma wand may be a disinfection device that can disinfect surfaces where dirt has been wiped off. It is possible to also the integrate a cleaning function into the plasma wand and thus develop a single cleaning and disinfection unit. In this case the only consumables are air and water. FIG. 3 depicts this embodiment. As shown in FIG. 3, an integrated brush attachment 302 or brush applicator 302 with water injector 304 is utilized. In this regard, the disclosed surface treatment device 300 includes a brush 302 coupled to the body 102, the brush 302 being configured to engage a surface 306 for treatment. The brush 302 may be a mechanical brush 302 configured to disturb or agitate a surface 306 to enhance gas transport. The surface treatment device 300 may also include a water dispenser 304 in fluid communication with the plasma source to provide plasma activated water to the surface 306 for treatment. In other words, gas activated by the plasma is dispersed out a plasma wand exhaust 308 and absorbed by the water from the water dispenser 304 and becomes a disinfecting solution. The water dispenser 304 may include soap water or simple tap water.

In this example, the proposed surface treatment device 300 allows scrubbing a surface 306 with the brush attachment 302 while the water dispenser 304 injects liquid water or mist to remove dirt. In this way, the clean moistened surface 306 is treated with the directed beam of reactive oxygen species. The liquid layer is therefore activated becoming plasma activated water which is antiseptic. As shown in FIG. 3, the brush 302 for dirt removal is positioned adjacent and downstream of the plasma wand exhaust 310 on the same side of the wand body 102. The brush attachment 302 is also positioned in-line with (i.e., directly underneath) the water dispenser 304, but on opposite sides of the wand body 102. However, other configurations are possible. For example, the plasma wand exhaust 308 may be positioned downstream of the brush 302 rather than upstream of the brush 302. In another example, the plasma wand exhaust 308 may be positioned centrally to the brush 302, such that the brush 302 encompasses or surrounds the plasma wand exhaust 308. For instance, one or more rows of brush bristles may be downstream of the plasma wand exhaust 308 and another one or more rows of brush bristles may be upstream of the plasma wand exhaust 308. Similarly, the plasma wand may have multiple brushes 302 and multiple plasma wand exhausts 308. In the example shown in FIG. 3, the plasma wand also includes a handle 310 attached to the body 102 at the upstream end and a gas/power feed line 312 attached to the handle 310. Other configurations and placements of the handle 310 and gas/power line 312 are possible.

An advantage of the example shown in FIG. 3 is to provide cleaning and sanitation as well as disinfection. The brush 302 physically clears surface 306 of dirt so that reactive species can disinfect the surface 306 below. Additionally, the plasma wand 300 can be used as a standalone cleaner and disinfector. By misting a soap solution or just tap water through brush section 302, the dirt can be removed. The plasma gas activates the liquid making it active and thus disinfecting. This plasma activated water is worked over the surface 306 by back and forth motion of the applicator on the surface 306 to be treated. In this case, the wand device 300 is an all in one cleaner—clean/sanitize as well as disinfect. This activated water is disinfecting and has a half-life, so residual disinfection is another advantage in that the activated water can keep the surface 306 clean for hours after application. In one example, this residual cleaning can last over 48 hours as long as the surface 306 is wet. As can be seen in FIG. 3, the brush 302 can be used to detach dirt from the surface 306. By spraying a thin film of water to the surface 306, dirt is removed more easily. Additionally, plasma activates this water to allow for disinfection as well. Back and forth motion of the applicator head on the surface 306 cleans the surface 306. The handle 310 is shown in FIG. 3 along with a power feed 312.

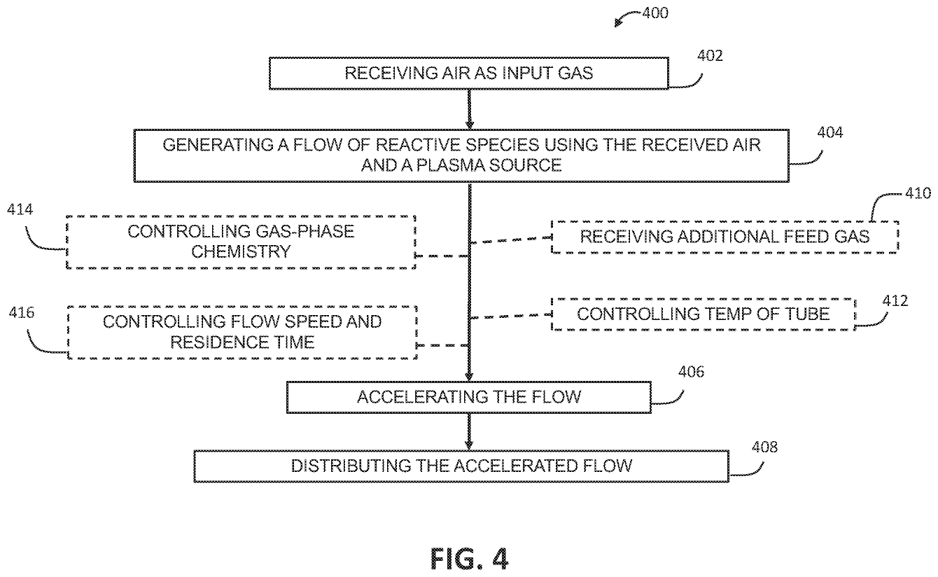

FIG. 4 illustrates a flow chart depicting a method 400 of treating a surface in accordance with one example. The method 400 of FIG. 4 may be implemented using the plasma wand or surface treatment device described above. For example, the method 400 of treating a surface may be used with a device having a body, a first inlet, an ionization wave generator, and a distributor, the body of the device having an inside portion, the ionization wave generator including a dielectric tube. In other examples, a different surface treatment device may be used. The method 400 may be implemented in the order shown but may be implemented in or according to any number of different orders. Additional, different, or fewer acts may be provided.

In the example of FIG. 4, the method 400 of treating a surface with a device may begin with act 402 in which air is received, by the first inlet, as input gas. Other input gases are possible.

The method 400 of treating a surface with a device may also include, at act 404, generating, by the ionization wave generator and a plasma source, a flow of reactive species based on the received input gas. The generating of act 404 may include activating, by an electrode of the ionization wave generator, the input gas along the dielectric tube.

The method 400 of treating a surface with a device may also include, at act 406, accelerating the flow of reactive species based on a geometry of the inside portion of the body of the device. In one example, the geometry may include a series of nozzles, such as a converging nozzle followed by a diverging nozzle. Other geometries and configurations are possible. For example, a converging only geometry may be used. In another example, a constant area geometry may be used. Accelerating the flow of reactive species at act 406 may also be achieved by adding pressure to the input gas via the first inlet. A combination of geometries and pressure may be used. In this way, a plasma working pressure may be above, at, or below ambient pressure, which may be used to further tailor the chemistry of the activated input gas.

The method 400 of treating a surface with a device may also include, at act 408, distributing, by the distributor, the accelerated flow of reactive species to treat the surface. The distributor may be a distributor plenum, such as the distributor plenum discussed above with regard to FIG. 2.

The method 400 of treating a surface with a device may further include additional acts, such as act 410, in which additional feed gas is received, by a second inlet, to mix with the generated flow of reactive species. The method 400 may also include, at act 412, controlling a temperature of the dielectric tube with the received additional feed gas. The method 400 may also include, at act 414, controlling gas-phase chemistry of the flow of reactive species with the received additional feed gas.

The method 400 of treating a surface with a device may further include, at act 416, controlling a flow speed and residence time of the flow of reactive species to optimize the generation of the flow of reactive species.

The disclosed plasma wand, or plasma device, may also be integrated into a system 500 for producing plasma-activated water. In this case the only consumables are air, water, and electricity. FIG. 5 depicts this embodiment. The plasma device may generate a plume of reactive oxygen species, as discussed above, for the purpose of disinfection and sterilization. In addition to the uses disclosed above, in one example this reactive gaseous plume may be directed underwater for the purpose of rendering a supply or volume of water drinkable or, in another example, for rendering the supply or volume of water, such as building tap water, into an antimicrobial solution. For example, ozone and peroxide may be deposited into a volume of water via the plasma device in the form of bubbles 507, as is illustrated in FIG. 5. The combination of peroxide and ozone in the volume of water in turn react to produce OH radicals. Taken altogether, these species via advanced oxidation decomposes organic matter in the volume of water. For example, the cell membranes of microbes may be decomposed via peroxidation. Shorter lived reactive species, such as singlet oxygen and super oxide that may also be emitted by the plasma device upon entry into the water as bubbles, may also drive OH radical production. Because the hydrogen peroxide and ozone are longer lived species, the plasma-activated water can retain residual disinfecting and sterilization power for days, after which the water sample reverts back to its original state. In this manner the plasma device may be a green sustainable approach that can be used to generate activated disinfectant on demand using simply air, water and electricity. In this regard, the disclosed devices, systems and methods may eliminate the need and expense of purchasing cleaners. The only reagent required is water. Therefore, the disclosed approach has the potential to be disruptive and essentially change the way antimicrobial solutions are accessed. The disclosed plasma-activated water approach using the disclosed plasma device may also be implemented within hand sanitizer stations. In this example the only consumables are again just air, water and electricity.

In one example, the system 500 of FIG. 5 may be used in a facility that requires frequent sanitation, such as that of a gym. One can image the apparatus or system of FIG. 5 being located in a confined or hidden space, such as a storage closet. As shown in FIG. 5, immersed in a holding water tank or water reservoir 502 is the applicator head 112 or distributor 112 of a plasma device 504, such as the plasma wand described above with respect to the other Figures. In another example, a hose or other conveyance system attached to the plasma device 504 may be fed into the water reservoir 502 to supply reactive gases generated by the plasma device 504 to the water reservoir 502. The water tank 502 may be fed domestic, potable water via a water flow controller 506 which is controlled by the system's programmable logic controller (PLC) 508. Also tied to the PLC 508 is a sensor 510 or bank of sensors 510 to monitor water quality such as ozone and peroxide concentration, water temperature and water level. Additionally, the power supply 512 that powers the plasma device attachment 504 is coupled to the PLC 508. The function of the PLC 508 is to maintain the correct water level, alert user of status, provide data analytics to the network, monitor water quality, and control plasma device 504 settings as well as monitor the device 504 and power supply 512 health. The system 500 or unit is expected to run on cycles, generating activated water via plasma device 504 action, which shuts off when the desired water conditions (reactive species concentration) are achieved. An agitator (not shown) may gently stir the solution for optimal mixing. A user needing a bottle of disinfectant would use the output spigot 514. When the reservoir's 502 water level is below a threshold, the tank 502 will then autofill and the plasma device 504 would operate for another cycle of duration depending on feedback from the chemical sensors 510. In this manner the supply chain of sterilizers and disinfectants can be eliminated.

In another example, the mix of reactive species produced by the plasma wand 504 of the system 500 of FIG. 5 may be used for water treatment, such as, for example, rendering water potable, or drinkable. The ability of controlling gas phase plasma chemistry allows the delivered reactive species dose to be tailored to disinfect water as well as decompose organic toxins in the water. In one example, organic compounds such as textile mill dyes may be disinfected and decomposed using the disclosed devices, systems, and methods. The disclosed gas dynamic design discussed above, including the nozzle and reactor subsection of the disclosed plasma wand, allows for the high-speed delivery of even short-lived species such as singlet oxygen and OH radicals to the water in addition to ozone and peroxide. Gas temperature and overall gas-phase kinetics may be adjusted through the control of primary and auxiliary input gas flow, which enables reactive nitrogen species and ozone concentrations to be controlled. More specifically, the ratio of primary input gas flow (i.e., the flow of reactive species generated by the plasma source) to the auxiliary input gas flow (i.e., the additional gas provided to mix with the generated flow of reactive gases) controls the concentrations of ozone and/or other reactive species (e.g., nitrogen species) in the water, such as NOx, nitrates, and nitrites. The ratio may be controlled and optimized for various applications, including, for instance, the production of potable water and the production of a disinfectant solution. In this case, the disclosed plasma wand may be able to deliver primarily reactive oxygen species to the water. The water may be rendered drinkable after this treatment since ozone in solution has a finite lifetime and the NOx species in solution can be reduced below drinking water maximum concentration levels. Additional steps, such as problematic post-processing steps, may be avoided. Additionally, because of the minimization of the NOx species production, the pH of the water being activated may not change appreciably either. The disclosed water treatment application is therefore a natural extension of the disclosed devices, systems, and methods that allow for control of gas phase chemistry. In this regard, the disclosed plasma wand is a tunable radical source with a range of applications aimed at activating substrates via the introduction of high oxidation power. The relative amounts of reactive nitrogen and other species may be tailored by adjusting the ratio between the primary to secondary injection, as described above, as well as by the application time of the device in the water to be activated.

FIG. 5 illustrates a system 500 for generating plasma-activated water in accordance with several examples, such as the examples discussed above. As shown in FIG. 5, the disclosed system 500 includes a water reservoir 502 configured to hold a volume of water. The water reservoir 502 may include a service lid 501 for allowing personnel access to the water reservoir 502. The water reservoir 502 may also include an inlet 505 having a water flow controller 506. The water reservoir 502 may also include an outlet 514. In one example, the inlet 505 is configured to provide domestic, potable water to the water reservoir 502 via the water flow controller 506. In another example, the inlet 505 is configured to provide non-potable, or undrinkable, water to the water reservoir 502 via the water flow controller 506. As discussed above, the outlet 514 may include an output spigot 514. The inlet 505 may also include a water shut off valve 503. The system 500 of FIG. 5 includes a plasma device 504 coupled to the water reservoir 502. The plasma device 504 of this system 500 may be designed and configured the same as the plasma wand described above with regard to FIGS. 1-3. In this example, the plasma device 504 includes a body 516 and a plasma source disposed within the body 516. The plasma device 504 may also include a power supply 512. The plasma device 504 may also include a distributor 518 in fluid communication with the body 516 and the plasma source. The plasma device 504 may be configured to generate a flow of reactive gases produced by the plasma source to activate the water, where a geometry of the body 516 of the plasma device 504 is configured to accelerate the flow of reactive gases, and where the plasma device 504 further includes an inlet port positioned to provide additional gas to mix with the generated flow of reactive gases. The body 516 of the plasma device 504 may include converging walls to define the geometry of the body 516 of the plasma device 504. In this example, the converging walls of the body 516 of the plasma device 504 are configured to gas dynamically accelerate reactive species into the water. In another example, the body 516 of the plasma device 504 may include diverging walls to define the geometry of the body 516. In one example, the additional gas controls a temperature of the flow of reactive gases. In another example, the additional gas controls gas-phase chemistry of the flow of reactive gases. In yet another example, the additional gas controls the speed of the flow of reactive gases. In yet a further example, a ratio of the reactive gases to the additional gas controls a concentration of reactive nitrogen and other species in the volume of water. In one example, the ratio falls in a range from about 5 to 1 to about 2 to 1, but other ratios may be used. Ratios near 5:1 may be suitable for the production of drinking water, while ratios near 2:1 may be suitable for the production of a disinfectant solution.

In one example, the system of FIG. 5 also includes an agitator configured to mix the reactive gases within the volume of water. The system of FIG. 5 also includes a sensor 510, or set of sensors 510, disposed inside the water reservoir 502. The sensor 510 or set of sensors 510 may be configured to measure a characteristic of the volume of water in the water reservoir 502. In one example, the characteristic is a concentration of a reactive gas. In another example, the characteristic is a concentration of one or more reactive nitrogen species in water solution. In one example, the reactive gases include ozone and peroxide. Alternatively or additionally, the characteristic is a temperature of the volume of water. Alternatively or additionally, the characteristic is indicative of the amount of a contaminant in the water. In yet another example, the characteristic is an amount of the volume of water. The system 500 of FIG. 5 also includes a controller 508 in communication with the water flow controller 506 of the inlet 505, the sensor 510 (or set of sensors 510), and the power supply 512 of the plasma device 504, where the controller 508 is configured to control water level of the volume of water via the water flow controller 506 and activation of the plasma device 504 via the power supply 512 based on the measured characteristic of the volume of water. In one example, the controller 508 is configured to discontinue operation of the plasma device 504 when the water level of the volume of water is below a predetermined threshold. In another example, the controller 508 is configured to discontinue operation of the plasma device 504 when a characteristic of the volume of water is above or below a predetermined threshold. For example, if a concentration of a reactive gas, reactive nitrogen species, or other toxin is below a predetermined threshold, the controller 508 may discontinue operation of the plasma device 504.

As shown above, the disclosed plasma wand utilizes nonequilibrium plasma as a source of reactive species combined with a properly shaped nozzle section to generate a high-speed reactive flow for delivery of short-lived species to a surface or to a volume of water. The disclosed surface treatment or water activation device separates the plasma stage from a secondary gas feed to control plasma gas temperature and gas phase chemistry. In this respect the plasma wand solves the problems associated with scaleup and tailored gas phase chemistry of conventional treatment and water activation devices. Further, the disclosed methods allow for shorter contact time relative to conventional cleaners and UV systems, while completely removing consumables, the need to dispose byproducts (e.g., wipes), and chemical contaminants.

The disclosed plasma wand has the potential to decrease the cost of consumables and added labor costs associated with increased cleaning and/or water treatment times, and may completely remove the negative environmental footprint of chemical disinfectants or additives.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A surface treatment device comprising:
a body;
a plasma source disposed within the body, the plasma source comprising:
a first inlet through the body; and
an ionization wave generator adjacent the first inlet to receive feedstock gas via the first inlet, the ionization wave generator comprising a dielectric tube that necks down to define an elongated throat;
a second inlet through the body, the second inlet being disposed at the elongated throat to provide further feedstock gas; and
an expansion nozzle disposed within the body downstream of the second inlet.

2. The surface treatment device of claim 1, wherein the ionization wave generator comprises an electrode that extends through the elongated throat.

3. The surface treatment device of claim 1, wherein the dielectric tube comprises a primary section adjacent the first inlet and a converging nozzle section between the primary section and the elongated throat.

4. The surface treatment device of claim 3, wherein the ionization wave generator comprises an electrode coaxially disposed in the dielectric tube, the electrode having a first section in the primary section and a second section in the elongated throat, the second section being narrower than the first section.

5. The surface treatment device of claim 1, wherein the second inlet is disposed at an axial position along the elongated throat to flush reactive species generated between the body and the elongated throat.

6. The surface treatment device of claim 1, wherein the second inlet is disposed at an axial position along the elongated throat to cool the dielectric tube along the elongated throat.

7. The surface treatment device of claim 1, wherein the feedstock gas comprises air.

8. The surface treatment device of claim 1, wherein the second inlet comprises a flow injector tube to provide the further feedstock gas.

9. The surface treatment device of claim 8, wherein the further feedstock gas provides a cooling flow to control a temperature of the elongated throat.

10. The surface treatment device of claim 1, further comprising a distributor plenum in fluid communication with the expansion nozzle.

11. The surface treatment device of claim 10, wherein the distributor plenum comprises a plurality of exit nozzles.

12. The surface treatment device of claim 11, wherein the plurality of exit nozzles are configured to distribute flow evenly through the plurality of exit nozzles.

13. The surface treatment device of claim 1, wherein the ionization wave generator is configured to generate a pulsed corona line-in-cylinder discharge, wherein reactive species are produced by the pulsed corona line-in-cylinder discharge.

14. The surface treatment device of claim 1, further comprising a water dispenser in fluid communication with the plasma source to provide plasma activated water to the surface for treatment.

15. A handheld surface treatment device comprising:
a grounded body comprising an inner hollow portion, the inner hollow portion having an upstream end and a downstream end;
a plasma source disposed in the inner hollow portion of the grounded body, the plasma source comprising:
a primary flow injector;
a dielectric tube comprising a primary section and an extended throat section, the primary section tapering down to the extended throat section, such that the extended throat section is narrower than the primary section; and
an electrode coaxially disposed in the primary section and the extended throat section of the dielectric tube;
a secondary flow injector through a wall of the grounded body, the secondary flow injector in fluid communication with the inner hollow portion of the grounded body; and
a distributor in fluid communication with the downstream end of the inner hollow portion of the grounded body.

16. The handheld surface treatment device of claim 15, wherein the primary flow injector is adjacent the upstream end of the inner hollow portion of the grounded body.

17. The handheld surface treatment device of claim 15, wherein the inner hollow portion comprises a tubular section adjacent the upstream end and a nozzle section adjacent the downstream end.

18. The handheld surface treatment device of claim 17, wherein the extended throat section of the dielectric tube extends from the tubular section into the nozzle section of the inner hollow portion of the grounded body.

19. The handheld surface treatment device of claim 17, wherein the secondary flow injector is disposed upstream of the nozzle section of the inner hollow portion of the grounded body.

20. A method of treating a surface with a device, the device comprising a body, a first inlet, an ionization wave generator, and a distributor, the body having an inside portion, the ionization wave generator comprising a dielectric tube, the method comprising:
receiving, by the first inlet, air as input gas;
generating, by the ionization wave generator and a plasma source, a flow of reactive species based on the received input gas;
accelerating the flow of reactive species based on a geometry of the inside portion of the body of the device; and
distributing, by the distributor, the accelerated flow of reactive species to treat the surface.

21. The method of claim 20, wherein the generating comprises activating, by an electrode of the ionization wave generator, the input gas along the dielectric tube.

22. The method of claim 20, further comprising receiving, by a second inlet, additional feed gas to mix with the generated flow of reactive species.

23. The method of claim 22, further comprising controlling a temperature of the dielectric tube with the received additional feed gas.

24. The method of claim 22, further comprising controlling gas-phase chemistry of the flow of reactive species with the received additional feed gas.

25. The method of claim 20, further comprising controlling a flow speed and residence time of the flow of reactive species to optimize the generation of the flow of reactive species.

26. The method of claim 20, further comprising providing, by a water source coupled to the body of the device, water into the body of the device, the water source being in fluid communication with the accelerated flow of reactive species, such that the water absorbs at least a portion of the reactive species, wherein distributing the accelerated flow comprises dispensing the water through a brush coupled to the body of the device to clean and disinfect the surface.

27. A system for generating plasma-activated water, the system comprising:
a water reservoir configured to hold a volume of water; and
a plasma device coupled to the water reservoir, the plasma device comprising a body and a plasma source disposed within the body, wherein the plasma device is configured to generate a flow of reactive gases produced by the plasma source to activate the water, wherein a geometry of the body of the plasma device is configured to accelerate the flow of reactive gases, and wherein the plasma device further comprises an inlet port positioned to provide additional gas to mix with the generated flow of reactive gases.

28. The system of claim 27, wherein the body of the plasma device comprises converging walls to define the geometry of the body of the plasma device configured to accelerate the flow of reactive gases.

29. The system of claim 27, wherein the water reservoir comprises an inlet having a water flow controller, the system further comprising:
a sensor disposed inside the water reservoir, the sensor being configured to measure a characteristic of the volume of water in the water reservoir; and
a controller in communication with the water flow controller of the inlet, the sensor, and a power supply of the plasma device,
wherein the controller is configured to control a water level of the volume of water via the water flow controller and activation of the plasma device via the power supply based on the measured characteristic of the volume of water.

30. The system of claim 29, wherein the characteristic is a concentration of a reactive gas.

31. The system of claim 29, wherein the plasma device is configured to control a temperature of the flow of reactive gases via the additional gas.

32. The system of claim 27, wherein the plasma device is configured to control a gas-phase chemistry of the flow of reactive gases via the additional gas.

33. The system of claim 27, wherein the plasma device is configured to control a ratio of the reactive gases to the additional gas to control a concentration of reactive species in the volume of water.

34. The system of claim 33, wherein the reactive species comprises reactive nitrogen species.

35. The system of claim 33, wherein the ratio falls in a range from about 5 to 1 to about 2 to 1.
